(19) United States
(12) Patent Application Publication
(10) Pub. No.: US 2009/0262559 A1
(43) Pub. Date: Oct. 22, 2009

(54) SEMICONDUCTOR DEVICE, AND ENERGY TRANSMISSION DEVICE USING THE SAME

(76) Inventor: Saichirou KANEKO, Kyoto (JP)

Correspondence Address: MCDERMOTT WILL & EMERY LLP, 600 13TH STREET, NW, WASHINGTON, DC, 20005-3096, US

(21) Appl. No.: 12/421,156

(22) Filed: Apr. 9, 2009

(30) Foreign Application Priority Data
Apr. 18, 2008 (JP) 2008-108859

(51) Int. Cl. H02M 3/335; H01L 29/739

(52) U.S. Cl. 363/21.04; 257/141; 363/20; 257/E29.197

(57) ABSTRACT

A semiconductor device includes: a high breakdown voltage semiconductor element including a switching element and a JFET element; and a sense element. The sense element includes a first drift region of a first conductivity type, a first base region of a second conductivity type, a first source region of a first conductivity type, a first gate insulating film, a first drain region of a first conductivity type, a sense electrode electrically connected to the first source region, a first gate electrode, and a first drain electrode electrically connected to the first drain region. The first gate electrode of the sense element and the second gate electrode of the switching element are connected to each other. The first drain electrode of the sense element and the electrode shared by the switching element and the JFET element are connected to each other.

### CROSS-REFERENCE TO RELATED APPLICATIONS

This application claims priority under 35 U.S.C. §119(a) based on Japanese Patent Application No. 2008-108859 filed on Apr. 18, 2008, the entire contents of which are hereby incorporated by reference.

### BACKGROUND

The present invention relates to a semiconductor device, and an energy transmission device using the semiconductor device. More particularly, the present invention relates to a semiconductor device for repeatedly conducting and blocking a main current in a switching power supply unit such as an energy transmission device.

A conventional semiconductor device will now be described with reference to FIG. 6 (e.g., see Patent Document 1: U.S. Pat. No. 4,811,075). A high breakdown voltage lateral semiconductor device is herein described as a specific example of the conventional semiconductor device. FIG. 6 is a cross-sectional view showing the structure of a conventional semiconductor device.

As shown in FIG. 6, a conventional semiconductor device 126 includes a high breakdown voltage semiconductor element 125 including a switching element 123 and a JFET (Junction Field-Effect Transistor) element 124. The semiconductor device 126 includes the following four types of electrodes: a source electrode 112; a gate electrode 113; a first drain electrode (hereinafter, referred to as “drain electrode”) 114; and a second drain electrode (hereinafter, referred to as “TAP electrode”) 115.

An N-type drift region 102 is formed at the surface of a P⁻-type semiconductor substrate 101. A P-type base region 103 is formed adjacent to the drift region 102 at the surface of the semiconductor substrate 101. An N⁺-type source region 104 is formed spaced apart from the drift region 102 at the surface of the base region 103. A P⁺-type base contact region 105 is formed adjacent to the source region 104 at the surface of the base region 103. A gate insulating film 106 is formed on the base region 103 between the source region 104 and the drift region 102. An N⁺-type first drain region 107 is formed spaced apart from the base region 103 at the surface of the drift region 102. An N⁺-type second drain region 108 is formed spaced apart from the first drain region 107 at the surface of the drift region 102.

A P-type first top semiconductor layer 109a is formed spaced apart from the first drain region 107 at the surface of the drift region 102 between the base region 103 and the first drain region 107. The first top semiconductor layer 109a is electrically connected to the base region 103 at a position not shown in the figure. A P-type second top semiconductor layer 109b is formed spaced apart from the first drain region 107 and the second drain region 108 at the surface of the drift region 102 between the first drain region 107 and the second drain region 108. The second top semiconductor layer 109b is electrically connected to the base region 103 at a position not shown in the figure.

The source electrode 112 is formed over the semiconductor substrate 101, and is electrically connected to the base region 103 and the source region 104. The gate electrode 113 is formed on the gate insulating film 106. The drain electrode 114 is formed over the semiconductor substrate 101, and is electrically connected to the first drain region 107. The TAP electrode 115 is formed over the semiconductor substrate 101, and is electrically connected to the second drain region 108.

First and second field insulating films 110a, 110b are formed on the first and second top semiconductor layers 109a, 109b, respectively. An interlayer film 116 is formed over the semiconductor substrate 101 with the first and second field insulating films 110a, 110b interposed therebetween.

When a voltage is applied between the drain electrode 114 and the source electrode 112 of the conventional semiconductor device, the drift region 102 near the second drain region 108 is depleted due to field effects. A voltage outputted to the TAP electrode 115 is therefore pinched off when it reaches, for example, about 50 V.

More specifically, as shown in FIG. 7, when a voltage lower than the pinch-off voltage is applied between the drain electrode 114 and the source electrode 112, a voltage which is supplied to the TAP electrode 115 is proportional to the voltage applied between the drain electrode 114 and the source electrode 112. When a voltage higher than the pinch-off voltage is applied between the drain electrode 114 and the source electrode 112, on the other hand, a voltage which is supplied to the TAP electrode 115 is equal to the pinch-off voltage. In other words, the voltage which is supplied to the TAP electrode 115 has a fixed value, and is lower than the voltage applied between the drain electrode 114 and the source electrode 112.

As described above, in the conventional semiconductor device 126, the voltage which is supplied to the TAP electrode 115 in an on state is proportional to the voltage of the drain electrode 114, as shown in FIG. 7. An on-state voltage between the drain electrode 114 and the source electrode 112 in an on state can therefore be detected by the TAP electrode 115.

Even if a high voltage is applied to the drain electrode 114 in an off state, a voltage which is outputted to the TAP electrode 115 can be pinched off.

Operation of the conventional semiconductor device 126 will now be described.

When the source electrode 112 has a negative voltage and the gate electrode 113 has a positive voltage, the surface of a region which faces the gate electrode 113 with the gate insulating film 106 interposed therebetween in the base region 103 is reversed to an N-type region. A current can therefore be supplied between the drain electrode 114 and the source electrode 112 through the N-type region (on state). In other words, a current flowing between the drain electrode 114 and the source electrode 112 can be controlled by an electric field which is generated by applying a voltage to the gate electrode 113.

Even when the gate electrode 113 has the same potential as that of the source electrode 112 (off state) and a high voltage is applied to the drain electrode 114, a voltage which is outputted to the TAP electrode 115 can be pinched off by a depletion layer which spreads in the drift region 102 near the second drain region 108. The TAP electrode 115 can therefore be connected to a low voltage circuit (a specific example of the “low voltage circuit” is a control circuit which is included in a switching power supply unit having the conventional semiconductor device).

### SUMMARY

However, the conventional semiconductor device 126 has the following problem.

In the conventional semiconductor device 126, an on-state voltage between the drain electrode 114 and the source electrode 112 in an on state can be detected by the TAP electrode 115, while a current flowing between the drain electrode 114 and the source electrode 112 in an on state cannot be detected.

Note that this problem can be solved by using, for example, a structure in which the source electrode is connected to a GND (ground) potential through a resistive element. In other words, by connecting the source electrode to the GND potential through the resistive element, a voltage which is applied to the resistive element varies according to a current flowing between the drain electrode and the source electrode. Therefore, the current flowing between the drain electrode and the source electrode can be detected by detecting this voltage. As the drain current increases, however, loss which is caused in the resistive element increases, thereby reducing energy efficiency.

In view of the above, it is an object of the present invention to provide a semiconductor device which is not only capable of detecting an on-state voltage between a drain electrode and a source electrode in an on state, but also capable of detecting a current flowing between the drain electrode and the source electrode in an on state with low loss, and to provide an energy transmission device using the semiconductor device.

In order to achieve the above object, a semiconductor device according to an aspect of the present invention is a semiconductor device which includes: a high breakdown voltage semiconductor element including a switching element and a JFET element; and a sense element. The sense element includes a first drift region of a first conductivity type formed at a surface of a semiconductor substrate, a first base region of a second conductivity type formed adjacent to the first drift region at the surface of the semiconductor substrate, a first source region of a first conductivity type formed spaced apart from the first drift region at a surface of the first base region, a first gate insulating film formed on the first base region between the first source region and the first drift region, a first drain region of a first conductivity type formed spaced apart from the first base region at a surface of the first drift region, a sense electrode formed over the semiconductor substrate and electrically connected to the first source region, a first gate electrode formed on the first gate insulating film, and a first drain electrode formed over the semiconductor substrate and electrically connected to the first drain region. The high breakdown voltage semiconductor element includes a second drift region of a first conductivity type formed at the surface of the semiconductor substrate, a second base region of a second conductivity type formed adjacent to the second drift region at the surface of the semiconductor substrate, a second source region of a first conductivity type formed spaced apart from the second drift region at a surface of the second base region, a second gate insulating film formed on the second base region between the second source region and the second drift region, a region (e.g., a second first-drain region of a first conductivity type) formed spaced apart from the second base region at a surface of the second drift region, a second second-drain region of a first conductivity type formed spaced apart from the region (e.g., the second first-drain region) at the surface of the second drift region, a second source electrode formed over the semiconductor substrate and electrically connected to the second base region and the second source region, a second gate electrode formed on the second gate insulating film, an electrode (e.g., a second first-drain electrode) formed over the semiconductor substrate and electrically connected to the region (e.g., the second first-drain region), and a second second-drain electrode formed over the semiconductor substrate and electrically connected to the second second-drain region. The first gate electrode of the sense element and the second gate electrode of the switching element are connected to each other. The first drain electrode of the sense element and the electrode (e.g., the second first-drain electrode) shared by the switching element and the JFET element are connected to each other.

According to the semiconductor device of the above aspect of the present invention, a current flowing between the second first-drain electrode and the second source electrode in an on state can be detected with low loss by a current flowing in the sense electrode. Moreover, as in the conventional example, an on-state voltage between the second first-drain electrode and the second source electrode in an on state can be detected by the second second-drain electrode (TAP electrode). Accordingly, the semiconductor device of the above aspect of the present invention is advantageous in that it is applicable to a wide range of device applications.

Moreover, even if a high voltage is applied to the second first-drain electrode, a voltage which is outputted to the second second-drain electrode (TAP electrode) can be pinched off by a depletion layer which spreads in the second drift region near the second second-drain region.

In the semiconductor device of the above aspect of the present invention, it is preferable that a conductivity type of the semiconductor substrate is a second conductivity type, and the high breakdown voltage semiconductor element further includes a second first-top semiconductor layer of a second conductivity type which is formed spaced apart from the second first-drain region at the surface of the second drift region between the second base region and the second first-drain region, and which is electrically connected to the second base region.

In this case, in the high breakdown voltage semiconductor element including the second first-top semiconductor layer, the concentration in the second drift region can be made higher than that in the second drift region of, for example, the high breakdown voltage semiconductor element which does not include the second first-top semiconductor layer. As a result, the on-state resistance of the semiconductor device can be reduced.

In the semiconductor device of the above aspect of the present invention, it is preferable that the sense element further includes a first top semiconductor layer of a second conductivity type which is formed spaced apart from the first drain region at the surface of the first drift region, and which is electrically connected to the first base region.

In the semiconductor device of the above aspect of the present invention, it is preferable that a conductivity type of the semiconductor substrate is a second conductivity type, and the high breakdown voltage semiconductor element further includes a second first-inner semiconductor layer of a second conductivity type which is formed spaced apart from the second first-drain region in the second drift region between the second base region and the second first-drain region, and which is electrically connected to the second base region.

In this case, in the high breakdown voltage semiconductor element including the second first-inner semiconductor layer, the concentration in the second drift region can be made higher than that in the second drift region of, for example, the high breakdown voltage semiconductor element including the second first-top semiconductor layer. As a result, the on-state resistance of the semiconductor device can be reduced.

In the semiconductor device of the above aspect of the present invention, it is preferable that the region is a collector region of a second conductivity type, the electrode is a collector electrode, and the collector electrode is electrically connected to the collector region.

An IGBT (Insulated Gate Bipolar Transistor) type semiconductor device can thus be provided. Since an IGBT bipolar element is used instead of a MOS (Metal Oxide Semiconductor) unipolar element as the switching element, the on-state resistance of the semiconductor device can further be reduced.

In the semiconductor device of the above aspect of the present invention, it is preferable that the region includes a collector region of a second conductivity type and a second first-drain region of a first conductivity type adjacent to the collector region, the electrode is a collector/drain electrode, and the collector/drain electrode is electrically connected to the collector region and the second first-drain region.

In this case, since electrons can be extracted from the second first-drain region upon turn-off, the switching speed can be increased as compared to, for example, the IGBT-type semiconductor device.

In order to achieve the above object of the present invention, an energy transmission device according to another aspect of the present invention includes: the semiconductor device of the above aspect of the present invention; a semiconductor integrated circuit including a control circuit for controlling switching of the semiconductor device which repeatedly conducts and blocks a main current; a DC (direct current) voltage source; and a transformer. The transformer includes a primary winding connected in series with the semiconductor device and the DC voltage source, and a first secondary winding connected to a load. The energy transmission device is configured so that electric power is supplied from the first secondary winding of the transformer to the load.

According to the energy transmission device of the above aspect of the present invention, a current flowing between the second first-drain electrode and the second source electrode in an on state can be detected with low loss by a current flowing in the sense electrode. Moreover, as in the conventional example, an on-state voltage between the second first-drain electrode and the second source electrode in an on state can be detected by the second second-drain electrode (TAP electrode).

In the energy transmission device of the above aspect of the present invention, it is preferable that the transformer further includes a second secondary winding connected to the control circuit, and the energy transmission device is configured so that electric power is supplied from the second secondary winding of the transformer to the control circuit.

In the energy transmission device of the above aspect of the present invention, it is preferable that the sense electrode is connected to the control circuit, and is connected to a ground potential through a resistor.

In this case, when the switching element is in an on state, a sense current flowing from the sense electrode is converted to a voltage by the resistor, and this voltage is detected by the control circuit, whereby a current flowing through the semiconductor device can be adjusted with low loss.

In the energy transmission device of the above aspect of the present invention, it is preferable that the semiconductor integrated circuit further includes a first transistor of a first conductivity type, the first transistor is connected to the second second-drain electrode through a first resistor, the first transistor is connected to a ground potential through a second resistor, and a gate potential of the first transistor is synchronized with a gate potential of the switching element.

In this case, an on-state voltage outputted to the second second-drain electrode (TAP electrode) can be detected by voltage division by the first resistor and the second resistor.

In the energy transmission device of the above aspect of the present invention, it is preferable that the semiconductor integrated circuit further includes a comparison voltage generator for outputting a comparison voltage based on a sense current flowing in the sense electrode, and a comparator. It is preferable that an on-state voltage outputted to the second second-drain electrode is applied to a non-inversion input terminal of the comparator, and the comparison voltage outputted from the comparison voltage generator is applied to an inversion input terminal of the comparator.

In this case, overheat detection can be more accurately performed by comparing the on-state voltage outputted to the second second-drain electrode (TAP electrode) and the comparison voltage outputted from the comparison voltage generator. Accordingly, a more reliable energy transmission device than the conventional energy transmission device can be implemented.

In the energy transmission device of the above aspect of the present invention, it is preferable that the semiconductor integrated circuit further includes a second transistor of a first conductivity type, the second second-drain electrode and the control circuit are connected to each other through a resistor and the second transistor, and the second transistor is controlled by the control circuit so as to be turned on when a voltage of a bias power supply terminal for supplying a current to the control circuit has a predetermined value or less.

In this case, driving electric power can be supplied to the control circuit by the second second-drain electrode (TAP electrode) upon starting. Since a low starting voltage which is required upon power-on can be generated by the second second-drain electrode, it is not necessary to provide a high breakdown voltage, high power resistor for supplying electric power. As a result, interconnection is simplified, and reduction in cost and reduction in size of a power supply circuit can be achieved accordingly.

As has been described above, according to the semiconductor device of the above aspect of the present invention and the energy transmission device using this semiconductor device, a current flowing between the second first-drain electrode and the second source electrode in an on state can be detected with low loss by a current flowing in the sense electrode. Moreover, as in the conventional example, an on-state voltage between the second first-drain electrode and the second source electrode in an on state can be detected by the second second-drain electrode (TAP electrode).

### BRIEF DESCRIPTION OF THE DRAWINGS

FIG. 1 is a cross-sectional view showing a structure of a semiconductor device according to a first embodiment of the present invention;

FIG. 2 is a circuit diagram of a switching power supply unit using the semiconductor device of the first embodiment of the present invention;

FIG. 3 is a graph showing characteristics of a switching element;

FIG. 4 is a cross-sectional view showing a structure of a switching element and a JFET element of a semiconductor device according to a second embodiment of the present invention;

FIG. 5 is a perspective view showing a structure of a switching element of a semiconductor device according to a third embodiment of the present invention;

FIG. 6 is a cross-sectional view showing a structure of a conventional semiconductor device; and

FIG. 7 is a graph showing pinch-off characteristics of a TAP electrode.

### DETAILED DESCRIPTION

Hereinafter, embodiments of the present invention will be described with reference to the accompanying drawings.

### First Embodiment

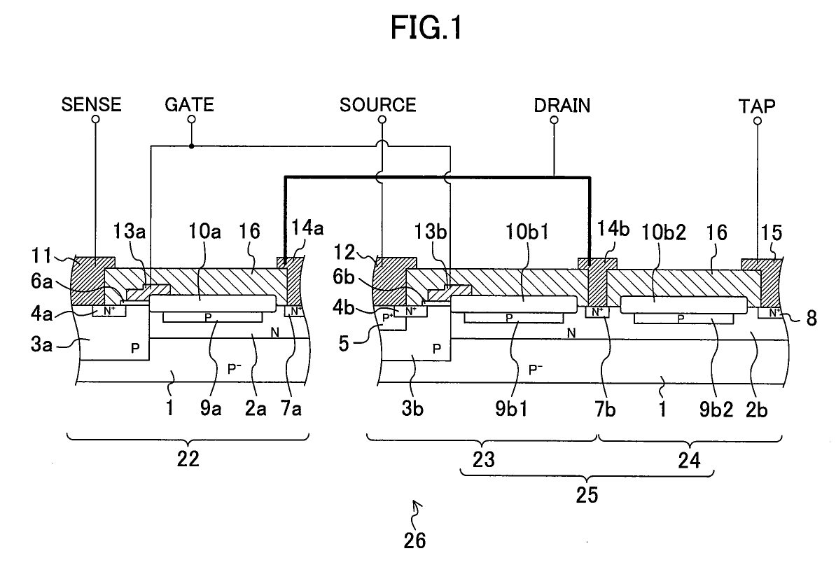

A structure of a semiconductor device according to a first embodiment of the present invention will be described with reference to FIG. 1. FIG. 1 is a cross-sectional view showing a structure of the semiconductor device according to the first embodiment of the present invention.

[Semiconductor Device]

A semiconductor device 26 of the first embodiment includes a high breakdown voltage semiconductor element 25 including a switching element 23 and a JFET element 24, as in the conventional example. The semiconductor device 26 of the first embodiment further includes a sense element 22 connected in parallel with the switching element 23.

The sense element 22 includes a sense electrode 11, a first gate electrode 13a, and a first drain electrode 14a. The high breakdown voltage semiconductor element 25 includes a second source electrode 12, a second gate electrode 13b, a second first-drain electrode (hereinafter, referred to as the “second drain electrode”) 14b, and a second second-drain electrode (hereinafter, referred to as “TAP electrode”) 15. The semiconductor device 26 thus includes five kinds of electrodes, that is, the sense electrode 11, the first and second gate electrodes 13a, 13b, the first and second drain electrodes 14a, 14b, the second source electrode 12, and the TAP electrode 15.

Note that the sense element 22 and the high breakdown voltage semiconductor element 25 are formed over a common semiconductor substrate 1.

Respective structures of the sense element 22 and the high breakdown voltage semiconductor element 25 will now be described sequentially.

[Sense Element]

As shown in FIG. 1, in the sense element 22, an N-type first drift region 2a is formed at the surface of a P⁻-type semiconductor substrate 1. A P-type first base region 3a is formed adjacent to the first drift region 2a at the surface of the semiconductor substrate 1. An N⁺-type first source region 4a is formed spaced apart from the first drift region 2a at the surface of the first base region 3a. A first gate insulating film 6a is formed on the first base region 3a between the first source region 4a and the first drift region 2a. An N⁺-type first drain region 7a is formed spaced apart from the first base region 3a at the surface of the first drift region 2a.

A P-type first top semiconductor layer 9a is formed spaced apart from the first drain region 7a at the surface of the first drift region 2a. The first top semiconductor layer 9a is electrically connected to the first base region 3a at a position not shown in the figure. A first field insulating film 10a is formed on the first top semiconductor layer 9a.

The sense electrode 11 is formed over the semiconductor substrate 1, and is electrically connected to the first source region 4a. The first gate electrode 13a is formed on the first gate insulating film 6a. The first drain electrode 14a is formed over the semiconductor substrate 1, and is electrically connected to the first drain region 7a.

[High Breakdown Voltage Semiconductor element]

In the high breakdown voltage semiconductor element 25, as shown in FIG. 1, an N-type second drift region 2b is formed at the surface of the semiconductor substrate 1. A P-type second base region 3b is formed adjacent to the second drift region 2b at the surface of the semiconductor substrate 1. An N⁺-type second source region 4b is formed spaced apart from the second drift region 2b at the surface of the second base region 3b. A P⁺-type base contact region 5 is formed adjacent to the second source region 4b at the surface of the second base region 3b. A second gate insulating film 6b is formed on the second base region 3b between the second source region 4b and the second drift region 2b. An N⁺-type second first-drain region 7b is formed spaced apart from the second base region 3b at the surface of the second drift region 2b. An N⁺-type second second-drain region 8 is formed spaced apart from the second first-drain region 7b at the surface of the second drift region 2b.

A P-type second first-top semiconductor layer 9b1 is formed spaced apart from the second first-drain region 7b at the surface of the second drift region 2b between the second base region 3b and the second first-drain region 7b. The second first-top semiconductor layer 9b1 is electrically connected to the second base region 3b at a position not shown in the figure. A P-type second second-top semiconductor layer 9b2 is formed spaced apart from the second first-drain region 7b and the second second-drain region 8 at the surface of the second drift region 2b between the second first-drain region 7b and the second second-drain region 8. The second second-top semiconductor layer 9b2 is electrically connected to the second base region 3b at a position not shown in the figure. Second first- and second-field insulating films 10b1, 10b2 are formed on the second first- and second-top semiconductor layers 9b1, 9b2, respectively.

The second source electrode 12 is formed over the semiconductor substrate 1, and is electrically connected to the second base region 3b and the second source region 4b. The second gate electrode 13b is formed on the second gate insulating film 6b. The second drain electrode 14b is formed over the semiconductor substrate 1, and is electrically connected to the second first-drain region 7b. The TAP electrode 15 is formed over the semiconductor substrate 1, and is electrically connected to the second second-drain region 8.

The sense element 22 and the high breakdown voltage semiconductor element 25 are thus formed on the common semiconductor substrate 1, and an interlayer film 16 is formed over the semiconductor substrate 1 with the first field insulating film 10a and the second first- and second-field insulating films 10b1, 10b2 interposed therebetween.

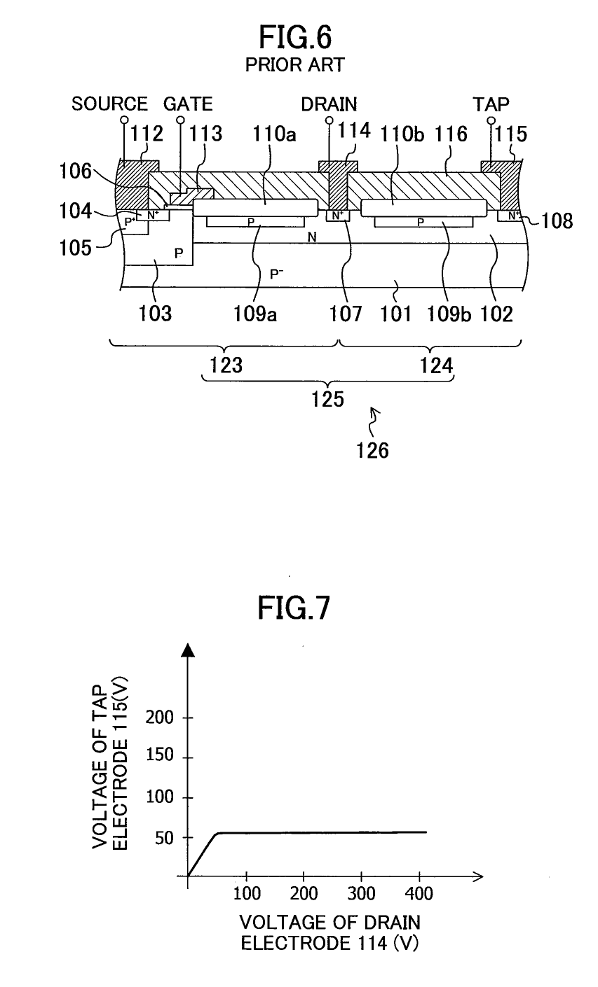

The semiconductor device 26 of the first embodiment is different from the conventional semiconductor device (see 126 in FIG. 6) in that the semiconductor device 26 further includes the sense element 22 connected in parallel with the switching element 23.

The switching element 23 and the sense element 22 are simultaneously turned on or off. In an on state, a current flowing in the sense element 22 is proportional to a current flowing in the switching element 23 according to the sense ratio. More specifically, provided that the current flowing in the sense element 22 is, for example, 1, the current flowing in the switching element 23 is 1,000.

According to the present embodiment, a current flowing between the second drain electrode 14b and the second source electrode 12 in an on state can be detected with low loss by a current flowing in the sense electrode 11. Moreover, as in the conventional example, an on-state voltage between the second drain electrode 14b and the second source electrode 12 in an on state can be detected by the TAP electrode 15. The semiconductor device of the present embodiment is therefore advantageous in that it is applicable to a wide range of device applications.

Note that the sense element 22 can be manufactured by a common semiconductor process without increasing the manufacturing cost.

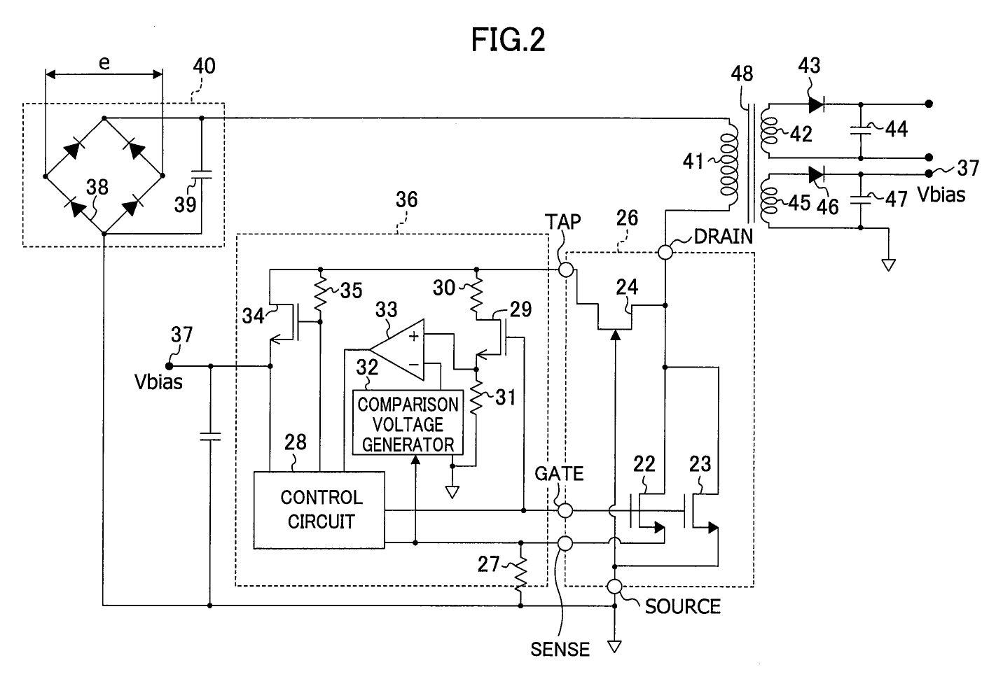

Hereinafter, a switching power supply unit according to the first embodiment of the present invention will be described with reference to FIG. 2. FIG. 2 is a circuit diagram of the switching power supply unit according to the first embodiment of the present invention.

[Switching Power Supply Unit]

As shown in FIG. 2, the switching power supply unit of the present embodiment includes the semiconductor device 26 of the present embodiment, a semiconductor integrated circuit 36, a DC voltage source 40, and a transformer 48. The semiconductor integrated circuit 36 includes a control circuit 28 for controlling switching of the semiconductor device 26 for repeatedly conducting and blocking a main current (for switching a main current between a flowing state and a non-flowing state). The transformer 48 includes a primary winding 41, a first secondary winding 42, and a second secondary winding 45. The primary winding 41 is connected in series with the semiconductor device 26 and the DC voltage source 40. The first secondary winding 42 is connected to a load, and the second secondary winding 45 is connected to the control circuit 28. The switching power supply unit of the present embodiment is configured so that electric power is supplied from the first secondary winding 42 of the transformer 48 to the load, and so that electric power is supplied from the second secondary winding 45 of the transformer 48 to the control circuit 28.

The sense electrode 11 is electrically connected to the control circuit 28, and is connected to a GND potential through a resistor 27.

Note that the semiconductor device 26 and the semiconductor integrated circuit 36 may either be formed on a common semiconductor substrate or separate semiconductor substrates.

Components of the switching power supply unit of the present embodiment will now be described sequentially.

[Semiconductor Device]

As shown in FIG. 2, the semiconductor device 26 of the present embodiment includes the sense element 22 in addition to the switching element 23 and the JFET element 24. The sense element 22 is connected in parallel with the switching element 23.

[Semiconductor Integrated Circuit]

The semiconductor integrated circuit 36 includes the control circuit 28. The control circuit 28 uses, for example, pulse width modulation or the like to control switching of the semiconductor device 26 which switches a main current between a flowing state and a non-flowing state.

The semiconductor integrated circuit 36 further includes an N-type first transistor 29 having a breakdown voltage of, for example, 100 V. The first transistor 29 is connected to the TAP electrode 15 through a first resistor 30. The first transistor 29 is further connected to the GND potential through a second resistor 31. The gate potential of the first transistor 29 is synchronized with that of the switching element 23.

The semiconductor integrated circuit 36 further includes a comparison voltage generator 32 and a comparator 33. The comparison voltage generator 32 outputs a comparison voltage based on a sense current flowing in the sense electrode 11. An on-state voltage outputted to the TAP electrode 15 is applied to a non-inversion input terminal of the comparator 33. A comparison voltage outputted from the comparison voltage generator 32 is applied to an inversion input terminal of the comparator 33.

The semiconductor integrated circuit 36 further includes an N-type second transistor 34 having a breakdown voltage of, for example, 100 V. The TAP electrode 15 and the control circuit 28 are connected to each other through a resistor 35 and the second transistor 34. The second transistor 34 is controlled by the control circuit 28 so as to be turned on when the voltage of a Vbias power supply terminal 37 has a predetermined value or less.

[DC Voltage Source]

The DC voltage source 40 is formed by a diode bridge 38 and a filter capacitor 39. An alternating current (AC) power source e is supplied to the DC voltage source 40.

[Transformer]

The transformer 48 includes the primary winding 41, the first secondary winding 42, and the second secondary winding 45. The first secondary winding 42 of the transformer 48 is connected to a diode 43 and a filter capacitor 44. The second secondary winding 45 of the transformer 48 is connected to a diode 46 and a filter capacitor 47.

The switching power supply unit of the present embodiment provides the following unique effect: As described above, a current flowing between the second drain electrode 14b and the second source electrode 12 in an on state can be detected with low loss by a current flowing in the sense electrode 11.

Moreover, the switching power supply unit of the present embodiment provides the following unique effect: As shown in FIG. 2, the sense electrode 11 is connected to the control circuit 28, and is connected to the GND potential through the resistor 27. Accordingly, when the switching element 23 is in an on state, a sense current which flows from the sense electrode 11 is converted to a voltage by the resistor 27, and this voltage is detected by the control circuit 28. A current flowing in the semiconductor device 26 can thus be adjusted with low loss.

Moreover, the switching power supply unit of the present embodiment provides the following unique effect: Overheat detection can be more accurately performed by comparing an on-state voltage outputted to the TAP electrode 15 and a comparison voltage outputted from the comparison voltage generator 32 by the comparator 33.

This unique effect will now be described specifically. In a specific example described below, it is assumed that overheat detection of the switching power supply unit of the present embodiment is performed at 140° C.

An on-state voltage outputted to the TAP electrode 15 is detected by the following structure: As shown in FIG. 2, a drain electrode of the first transistor 29 is connected to the TAP electrode 15 through the first resistor 30. A source electrode of the first transistor 29 is connected to the GND potential through the second resistor 31. The gate potential of the first transistor 29 is synchronized with that of the switching element 23. The first transistor 29 is thus turned on at the same time as the switching element 23 is turned on.

An on-state voltage outputted to the TAP electrode 15 upon turn-on of the switching element 23 at, for example, 140° C. can therefore be detected by voltage division by the first resistor 30 and the second resistor 31.

The comparison voltage is outputted from the comparison generator 32 by the structure described below. Note that, in a specific example described below, it is assumed that the on-state resistance of the switching element 23 has a positive correlation with the temperature, and the voltage of the TAP electrode 15 at a certain temperature (e.g., 140° C.) is uniquely determined with respect to a drain current flowing in the second drain electrode 14b.

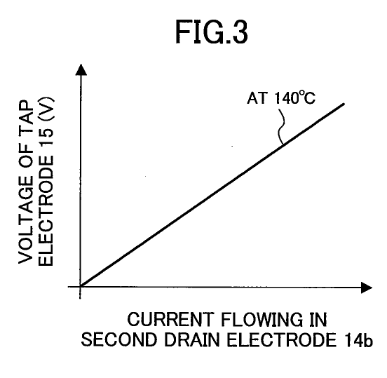

FIG. 3 shows the measurement result of the voltage of the TAP electrode 15 with respect to the drain current at a temperature of, for example, 140° C.

A sense current flowing from the sense electrode 11 is converted to a voltage by the resistor 27, and a drain current flowing in the second drain electrode 14b is obtained based on this voltage. A voltage of the TAP electrode 15 is obtained based on the obtained drain current and the result of FIG. 3, and the obtained voltage of the TAP electrode 15 (hereinafter, referred to as a “comparison voltage”) is outputted from the comparison voltage generator 32.

The on-state voltage outputted to the TAP electrode 15 is applied to the non-inversion input terminal of the comparator 33. The comparison voltage outputted from the comparison voltage generator 32 is applied to the inversion input terminal of the comparator 33. When the on-state voltage outputted to the TAP electrode 15 reaches the comparison voltage, it is determined that the semiconductor device 26 is in an overheated state (abnormal state). As a result, the comparator 33 outputs a positive voltage, and the control circuit 28 negatively biases the second gate electrode 13b to turn off the switching element 23.

The switching power supply unit thus provides the unique effect described above. In other words, overheat detection can be more accurately performed by comparing the on-state voltage outputted to the TAP electrode 15 and the comparison voltage generated by using the sense current flowing from the sense electrode 11. Accordingly, a more reliable switching power supply unit than the conventional switching power supply unit can be implemented.

Moreover, the switching power supply unit of the present embodiment provides the same effect as that of the conventional switching power supply unit, that is, the effect in which driving electric power can be supplied to the control circuit 28 by the TAP electrode 15 upon starting. More specifically, the voltage of the TAP electrode 15 is pinched off as described above. Therefore, even if a high voltage is applied from the primary winding 41 of the transformer 48 to the second drain electrode 14b, the voltage of the TAP electrode 15 is constant, that is, is equal to a pinch-off voltage (e.g., about 50 V). Therefore, the TAP electrode 15 can be connected to the control circuit 28 to supply driving electric power to the control circuit 28.

Operation of supplying driving electric power to the control circuit 28 by the TAP electrode 15 upon starting (upon power-on) will now be described.

The second transistor 34 is controlled by the control circuit 28 so as to be turned on when the voltage of the Vbias power supply terminal 37 has a predetermined value or less. Accordingly, after the AC power source e is supplied, a direct current which has been generated in the DC voltage source 40 and has flown through the primary winding 41 is partially supplied from the TAP electrode 15 of the JFET element 24 to the control circuit 28 through the second transistor 34 in an on state, whereby the control circuit 28 is started.

The switching element 23 then repeats the switching operation. As a result, a voltage is induced in the second secondary winding 45 of the transformer 48, and a current flows through the diode 46 and is supplied from the Vbias power supply terminal 37 to the control circuit 28. When the voltage of the Vbias power supply terminal 37 exceeds the predetermined value, the second transistor 34 is turned off, and the control circuit 28 operates in a steady state.

Since a low starting voltage which is required upon power-on can thus be generated by the TAP electrode 15, it is not necessary to provide a high breakdown voltage, high power resistor for supplying electric power. As a result, interconnection is simplified, and reduction in cost and reduction in size of a power supply circuit can be achieved accordingly.

Although not particularly shown in the figure, the timing the switching element 23 is turned on can be detected in the control circuit 28 by using a voltage resulting from resistance-dividing the potential of the TAP electrode 15.

Note that, in the specific example described in the present embodiment, the switching power supply unit is used as the energy transmission device. However, the present invention is not limited to this, and an AC inverter device or the like may be used as the energy transmission device.

In the specific example described in the present embodiment, the on-state resistance of the switching element 23 has a positive correlation with the temperature, as shown in FIG. 3. However, the present invention is not limited to this. The same effects can be obtained even when the on-state resistance of the switching element 23 has a negative correlation with the temperature.

In the specific example described in the present embodiment, the high breakdown voltage semiconductor element 25 has both the second first-top semiconductor layer 9b1 and the second second-top semiconductor layer 9b2, as shown in FIG. 1. However, the present invention is not limited to this, and a high breakdown voltage semiconductor element having, for example, only the second first-top semiconductor layer 9b1 may be used.

### Second Embodiment

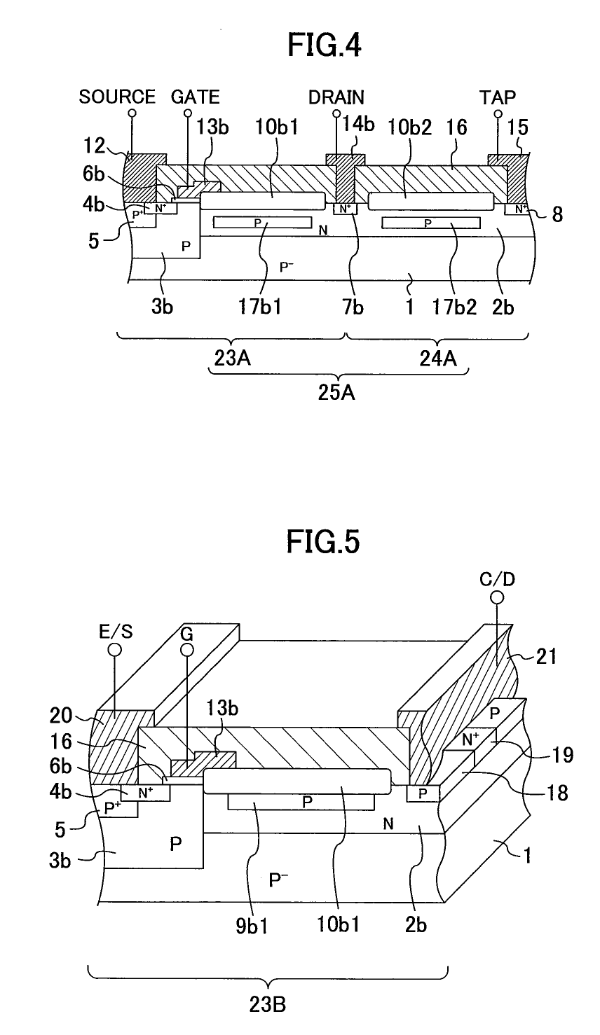

Hereinafter, a structure of a semiconductor device according to a second embodiment of the present invention will be described with reference to FIG. 4. FIG. 4 is a cross-sectional view showing a structure of a high breakdown voltage semiconductor element 25A in the semiconductor device of the second embodiment of the present invention. Note that, in FIG. 4, the same components as those of the first embodiment are denoted with the same reference numerals and characters as those of FIG. 1 of the first embodiment. The differences from the first embodiment will be mainly described in the second embodiment, and description of the common structure will be omitted as appropriate.

The second embodiment is different from the first embodiment in that the second first- and second-top semiconductor layers 9b1, 9b2 of the first embodiment are replaced with second first- and second-inner semiconductor layers 17b1, 17b2.

More specifically, in the first embodiment, the second first-top semiconductor layer 9b1 is formed spaced apart from the second first-drain region 7b at the surface of the second drift region 2b between the second base region 3b and the second first-drain region 7b, as shown in FIG. 1. Moreover, the second second-top semiconductor layer 9b2 is formed spaced apart from the second first- and second-drain regions 7b, 8 at the surface of the second drift region 2b between the second first-drain region 7b and the second second-drain region 8.

In the second embodiment, on the other hand, as shown in FIG. 4, the second first-inner semiconductor layer 17b1 is formed spaced apart from the second first-drain region 7b in the second drift region 2b between the second base region 3b and the second first-drain region 7b. The second second-inner semiconductor layer 17b2 is formed spaced apart from the second first- and second-drain regions 7b, 8 in the second drift region 2b between the second first-drain region 7b and the second second-drain region 8.

In the second embodiment, the second first- and second-top semiconductor layers 9b1, 9b2 are replaced with the second first- and second-inner semiconductor layers 17b1, 17b2. As a result, the concentration in the second drift region 2b of the second embodiment can be made higher than that in the second drift region 2b of the first embodiment, when the breakdown voltage of the high breakdown voltage semiconductor element 25A of the second embodiment is about the same as that of the high breakdown voltage semiconductor element 25 of the first embodiment. Accordingly, the on-state resistance of the semiconductor device can be reduced.

Moreover, the second drift region 2b under the second second-top semiconductor layer 9b2 is mainly depleted in the first embodiment, while the second drift region 2b around the second second-inner semiconductor layer 17b2 is mainly depleted in the second embodiment. A larger part of the second drift region 2b is thus depleted as compared to the first embodiment, whereby the voltage outputted to the TAP electrode 15 can be more easily pinched off.

Note that the high breakdown voltage semiconductor element 25A of the second embodiment can be manufactured by a common semiconductor process with less increase in manufacturing cost, as compared to the high breakdown voltage semiconductor element 25 of the first embodiment.

In the specific example described in the second embodiment, the high breakdown voltage semiconductor element 25A has both the second first-inner semiconductor layer 17b1 and the second second-inner semiconductor layer 17b2, as shown in FIG. 4. However, the present invention is not limited to this, and a high breakdown voltage semiconductor element having, for example, only the second first-inner semiconductor layer 17b1 may be used.

### Third Embodiment

Hereinafter, a structure of a semiconductor device according to a third embodiment of the present invention will be described with reference to FIG. 5. FIG. 5 is a perspective view of a switching element 23B in the semiconductor device of the third embodiment of the present invention. Note that, in FIG. 5, the same components as those of the first embodiment are denoted with the same reference numerals and characters as those of FIG. 1 of the first embodiment. The differences from the first embodiment will be mainly described in the third embodiment, and description of the common structure will be omitted as appropriate.

The third embodiment is different from the first embodiment in that a collector region (see 18 in FIG. 5) is provided in addition to the second first-drain region to form an IGBT switching element. The differences between the first embodiment and the third embodiment will now be described in detail.

Firstly, the second first-drain region 7b is formed at the surface of the second drift region 2b in the first embodiment, as shown in FIG. 1, while a P-type collector region 18 and an N⁺-type second first-drain region 19 adjacent to the collector region 18 are formed at the surface of the second drift region 2b in the third embodiment, as shown in FIG. 5.

Secondly, the second source electrode 12 which is electrically connected to the second base region 3b and the second source region 4b is provided in the first embodiment, while an emitter/source electrode 20 which is electrically connected to the second base region 3b and the second source region 4b is provided in the third embodiment.

Thirdly, the second drain electrode 14b which is electrically connected to the second first-drain region 7b is provided in the first embodiment, while a collector/drain electrode 21 which is electrically connected to the collector region 18 and the second first-drain region 19 is provided in the third embodiment.

When a positive bias is applied between the collector/drain electrode 21 and the emitter/source electrode 20 and a positive voltage is applied to the second gate electrode 13b in the switching element 23B, a current starts to flow from the second first-drain region 19 through the second source region 4b to the emitter/source electrode 20 (MOSFET operation). When the potential of the second drift region 2b under the collector region 18 becomes smaller than that of the collector region 18 by about 0.6 V, holes are injected from the collector region 18 into the second drift region 2b, whereby the operation switches from MOSFET operation to IGBT operation. As a result, the on-state resistance of the semiconductor device can further be reduced.

Moreover, since electrons can be extracted from the second first-drain region 19 upon turn-off, the switching speed can be increased.

It has been experimentally found that adjustment of a drain current by detecting an on-state voltage by the TAP electrode is difficult especially before and after the operation switches from MOSFET operation to IGBT operation. It is therefore desirable to adjust a drain current not by using detection of the on-state voltage by the TAP electrode as in the conventional example, but by using a sense current flowing from the sense electrode as in the present invention.

Note that the switching element 23B of the third embodiment can be manufactured by a common semiconductor process with less increase in manufacturing cost, as compared to the switching element 23 of the first embodiment.

In the specific example of the structure described in the present embodiment, the collector region 18 is provided in addition to the second first-drain region 19. However, the present invention is not limited to this. For example, only a collector region may be provided instead of the second first-drain region.

In the first through third embodiments, a lateral semiconductor device in which a current flows in a lateral direction to the semiconductor substrate 1 is described as a specific example of a semiconductor device. However, the present invention is not limited to this, and the semiconductor device of the present invention may be a vertical semiconductor device in which a current flows in a vertical direction to the semiconductor substrate.

In the first and third embodiments, the semiconductor device having the second first- and second-top semiconductor layers 9b1, 9b2 at the surface of the second drift region 2b is described as a specific example of a semiconductor device. In the second embodiment, the semiconductor device having the second first- and second-inner semiconductor layers 17b1, 17b2 in the second drift region 2b is described as a specific example of a semiconductor device. However, the present invention is not limited to these. The present invention is applicable also to a semiconductor device having neither top semiconductor layers and nor inner semiconductor layers.

As described above, in the present invention, a current flowing between a drain electrode and a source electrode in a high breakdown voltage semiconductor element in an on state can be detected with low loss by using a current flowing in a sense electrode. The present invention is therefore useful for a semiconductor device including a high breakdown voltage semiconductor element, and an energy transmission device using the semiconductor device.

What is claimed is:

1. A semiconductor device, comprising:
a high breakdown voltage semiconductor element including a switching element and a JFET element; and
a sense element, wherein
the sense element includes
a first drift region of a first conductivity type formed at a surface of a semiconductor substrate,
a first base region of a second conductivity type formed adjacent to the first drift region at the surface of the semiconductor substrate,
a first source region of a first conductivity type formed spaced apart from the first drift region at a surface of the first base region,
a first gate insulating film formed on the first base region between the first source region and the first drift region,
a first drain region of a first conductivity type formed spaced apart from the first base region at a surface of the first drift region,
a sense electrode formed over the semiconductor substrate and electrically connected to the first source region,
a first gate electrode formed on the first gate insulating film, and
a first drain electrode formed over the semiconductor substrate and electrically connected to the first drain region,
the high breakdown voltage semiconductor element includes
a second drift region of a first conductivity type formed at the surface of the semiconductor substrate,
a second base region of a second conductivity type formed adjacent to the second drift region at the surface of the semiconductor substrate,
a second source region of a first conductivity type formed spaced apart from the second drift region at a surface of the second base region,
a second gate insulating film formed on the second base region between the second source region and the second drift region,
a region formed spaced apart from the second base region at a surface of the second drift region,
a second second-drain region of a first conductivity type formed spaced apart from the region at the surface of the second drift region,
a second source electrode formed over the semiconductor substrate and electrically connected to the second base region and the second source region,
a second gate electrode formed on the second gate insulating film,
an electrode formed over the semiconductor substrate and electrically connected to the region, and
a second second-drain electrode formed over the semiconductor substrate and electrically connected to the second second-drain region,
the first gate electrode of the sense element and the second gate electrode of the switching element are connected to each other, and
the first drain electrode of the sense element and the electrode shared by the switching element and the JFET element are connected to each other.

2. The semiconductor device of claim 1, wherein
the region is a second first-drain region of a first conductivity type, and
the electrode is a second first-drain electrode.

3. The semiconductor device of claim 2, wherein
a conductivity type of the semiconductor substrate is a second conductivity type, and
the high breakdown voltage semiconductor element further includes
a second first-top semiconductor layer of a second conductivity type which is formed spaced apart from the second first-drain region at the surface of the second drift region between the second base region and the second first-drain region, and which is electrically connected to the second base region.

4. The semiconductor device of claim 3, wherein
the sense element further includes
a first top semiconductor layer of a second conductivity type which is formed spaced apart from the first drain region at the surface of the first drift region, and which is electrically connected to the first base region.

5. The semiconductor device of claim 2, wherein
a conductivity type of the semiconductor substrate is a second conductivity type, and
the high breakdown voltage semiconductor element further includes
a second first-inner semiconductor layer of a second conductivity type which is formed spaced apart from the second first-drain region in the second drift region between the second base region and the second first-drain region, and which is electrically connected to the second base region.

6. The semiconductor device of claim 1, wherein
the region is a collector region of a second conductivity type,
the electrode is a collector electrode, and
the collector electrode is electrically connected to the collector region.

7. The semiconductor device of claim 1, wherein
the region includes a collector region of a second conductivity type and a second first-drain region of a first conductivity type adjacent to the collector region,
the electrode is a collector/drain electrode, and
the collector/drain electrode is electrically connected to the collector region and the second first-drain region.

8. An energy transmission device, comprising:
the semiconductor device of claim 1;
a semiconductor integrated circuit including a control circuit for controlling switching of the semiconductor device which repeatedly conducts and blocks a main current;
a DC voltage source; and
a transformer, wherein
the transformer includes
a primary winding connected in series with the semiconductor device and the DC voltage source, and
a first secondary winding connected to a load, and
the energy transmission device is configured so that electric power is supplied from the first secondary winding of the transformer to the load.

9. The energy transmission device of claim 8, wherein
the transformer further includes a second secondary winding connected to the control circuit, and
the energy transmission device is configured so that electric power is supplied from the second secondary winding of the transformer to the control circuit.

10. The energy transmission device of claim 8, wherein
the sense electrode is connected to the control circuit, and is connected to a ground potential through a resistor.

11. The energy transmission device of claim 8, wherein
the semiconductor integrated circuit further includes a first transistor of a first conductivity type,
the first transistor is connected to the second second-drain electrode through a first resistor,
the first transistor is connected to a ground potential through a second resistor, and
a gate potential of the first transistor is synchronized with a gate potential of the switching element.

12. The energy transmission device of claim 11, wherein
the semiconductor integrated circuit further includes
a comparison voltage generator for outputting a comparison voltage based on a sense current flowing in the sense electrode, and
a comparator,
an on-state voltage outputted to the second second-drain electrode is applied to a non-inversion input terminal of the comparator, and
the comparison voltage outputted from the comparison voltage generator is applied to an inversion input terminal of the comparator.

13. The energy transmission device of claim 8, wherein
the semiconductor integrated circuit further includes a second transistor of a first conductivity type,
the second second-drain electrode and the control circuit are connected to each other through a resistor and the second transistor, and
the second transistor is controlled by the control circuit so as to be turned on when a voltage of a bias power supply terminal for supplying a current to the control circuit has a predetermined value or less.
